(19) United States
(12) Patent Application Publication
(10) Pub. No.: US 2006/0083927 A1
(43) Pub. Date: Apr. 20, 2006

(54) Thermal interface incorporating nanotubes

(75) Inventor: James R. Von Ehr II, Richardson, TX (US)

Correspondence Address: HAYNES AND BOONE, LLP, 901 MAIN STREET, SUITE 3100, DALLAS, TX, 75202, US

(73) Assignee: Zyvex Corporation, Richardson, TX (US)

(21) Appl. No.: 10/967,002

(22) Filed: Oct. 15, 2004

(51) Int. Cl. B32B 9/00; C23C 16/00; B05D 1/32; B05D 5/00; B05D 3/00

(52) U.S. Cl. 428/408; 427/299; 427/282; 427/248.1; 118/715

(57) ABSTRACT

A thermal interface device that includes nanotubes, projecting from opposing surfaces of a substrate, methods for fabricating such a thermal interface device, and methods for applying such a thermal interface device to a heat-generating device. The nanotubes are substantially perpendicularly aligned with respect to the substrate.

### TECHNICAL FIELD

The present disclosure relates generally to a thermal interface that includes nanotubes projecting from opposing surfaces of a substrate, methods for fabricating such a thermal interface, and methods for applying such a thermal interface to transfer heat between a heat-generating surface and a heat-sinking surface.

### BACKGROUND

There are many applications where heat must be transferred between objects. In the electronics industry, for example, heat from an electronic module or other heat generating device is transferred to a heat dissipating device, such as a heat sink. The thermal interface between these devices controls how much heat is transferred between them.

One type of thermal interface consists of a heat-conducting material embedded in a structural matrix. Carbon fibers, nanotubes, nanoplatelets, nanofibrils and similar materials have the ability to conduct heat when aligned. Carbon nanotubes are known to be superb thermal conductors. Thus, using aligned nanotubes as the heat-conducting material in a structural matrix, such as a polymeric matrix, is a desirable application. However, alignment of nanotubes sufficient to provide a desirable device for application as a thermal interface is difficult to obtain because of nanotube mobility restrictions created by interactions between the nanotubes and the polymer molecules of the matrix. High concentrations of nanotubes, required for high thermal conductivity, make the polymer-nanotube composite extremely viscous and hard to process.

Nanotubes are particularly desirable for creating a thermal interface because their flexibility and small diameter allows them to bend and deform to make intimate contact with surfaces that may be microscopically rough. Such surfaces are unable to achieve intimate thermal contact when pressed together without a thermal interface material between them. However, nanotubes as generally produced cannot be used directly as thermal interface materials because they cannot be aligned between two surfaces and held in position.

The present disclosure provides a thermal interface that includes aligned nanotubes projecting from both sides of a substrate, and methods for fabricating such a thermal interface. The embodiment of such a thermal interface in a component that may be handled is called a thermal interface device.

### BRIEF DESCRIPTION OF THE DRAWINGS

The present disclosure is best understood from the following detailed description when read with the accompanying figures. It is emphasized that various features are not drawn to scale. Referring now to the figures:

FIG. 1 illustrates a flow-chart diagram of a method for preparing a thermal interface device comprising arrays of aligned nanotubes.

FIG. 2 illustrates a top view of one example of a substrate prepared for use as a thermal interface device according to the method illustrated by FIG. 1.

FIG. 3 illustrates one example of an application system for use in conditioning for nanotube growth according to the method illustrated in FIG. 1.

FIG. 4 illustrates another example of an application system for use in conditioning for nanotube growth according to the method illustrated in FIG. 1.

FIG. 5 illustrates a cross-section of the substrate illustrated in FIG. 2, with nanotubes grown on opposing surfaces of a substrate.

FIG. 6 illustrates a perspective view of the substrate illustrated in FIG. 5.

FIG. 7 illustrates a system for preparing a thermal interface according to the method illustrated in FIG. 1.

FIG. 8 illustrates an example of a system for applying a thermal interface device according to the present examples to a heat-generating device.

### DETAILED DESCRIPTION

It is to be understood that the present disclosure provides many different embodiments, or examples, for implementing different features of the disclosed technology. Specific examples of components and arrangements are described to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various examples and/or configurations discussed.

The present disclosure provides a method for preparing a thermal interface device and for applying such a thermal interface device to provide thermal conductivity between components such as a heat source and a heat sink. The present method produces nanotubes in arranged arrays so as to maximize heat transfer. The method includes conditioning opposing areas (interchangeably referred to as “coupons”) of a substrate for nanotube growth, and growing thermally conductive nanotubes on both sides of the coupons. In further examples, the present method includes preparing a substrate prior to conditioning, and post-processing the substrate after the nanotubes are grown to make the coupons ready for use as thermal interface devices.

A system for preparing a thermal interface device and for applying such a thermal interface device between a heat-generating device and a heat-sinking device is also described. This system includes a nanotube conditioning subsystem and a nanotube growth subsystem. In the nanotube conditioning subsystem, nanotube growth areas are conditioned on opposing surfaces of a substrate by one or more of application of a mask, application of a catalyst, or local activation of the substrate. In the nanotube growth subsystem, nanotubes are grown by chemical vapor deposition on each of the opposing surfaces of nanotube growth areas defined on the substrate. A thermal interface device comprises the opposing surfaces of the nanotube growth areas with nanotubes grown thereon. Optionally, the thermal interface preparation system includes a post-processing subsystem, in which the nanotube growth areas are further processed for use as thermal interface devices. In addition, the system may also optionally include a substrate preparation subsystem, which precedes the nanotube conditioning subsystem, and in which surface features of the substrate are defined.

Thermal interface devices comprising arrays of nanotubes grown on opposing surfaces of a substrate are also disclosed herein. Nanotubes in the arrays grown according to the examples illustrated herein are relatively dense, and so have a high heat transfer capability. The nanotubes are grown substantially perpendicularly aligned with respect to the substrate so heat transfer is substantially in the direction of the tubes. Moreover, the aligned nanotubes grown according to the examples illustrated herein are substantially the same length, in contrast to methods where nanotubes of varying lengths are aligned during their introduction into a host matrix. By growing nanotubes on opposing sides of a substrate as described herein, a thermal interface device with exceptional heat-dissipating capacity results. Thus, a thermal interface device prepared according to the present examples has a high thermal conductivity in the direction of desired heat flow.

The thermal interface device may be electrically conducting or electrically insulating, depending on the type of substrate and nanotube. According to the present examples, the substrate comprises a material with one or more of a capability to withstand high temperatures, such as temperatures greater than about 300 C, preferably greater than about 600 C, and a high capacity for thermal conductivity. In certain examples, the substrate is a metal, such as steel, stainless steel, or nickel, while in other examples, the substrate is a non-metal material such as glass and ceramics. According to some examples, the substrate comprises a material that is electrically conductive, while in other examples, the substrate comprises a material that is electrically insulating. According to another example, the substrate is a sandwich of electrically conducting and electrically insulating materials. Whether the material selected for the substrate is electrically conducting or electrically insulating depends on the desired application for the thermal interface device. For example, some applications may require thermal conductance, but high electrical resistance. Such applications may be satisfied by growing the nanotubes on a thermally conducting but electrically insulating substrate.

Another approach would be to grow different types of nanotubes on the different faces such that the two faces have different mechanical, electrical, or thermal properties. Although the present examples are described as growing carbon nanotubes on both sides of the substrate, growing different types of nanotubes on opposing surfaces of the substrate could be implemented by the methods and systems described herein. For example, different sized nanotubes could be grown on opposing surfaces of the substrate by applying different sized catalyst particles to the opposing surfaces. The diameter of the catalyst particle influences the size of the tube. In another example, different catalyst materials could preferentially catalyze different types of tubes on opposing surfaces of a substrate. In yet another example, different gases impinging on each surface could grow different types of tubes. In yet another example, different conditions applied to each surface, for example an RF plasma on one side, could lead to different types of tubes.

Both multi-walled nanotubes (MWNTs) and single-wall nanotubes (SWNTs) are suitable for use with the present invention. Methods for catalytic growth of carbon MWNTs and carbon SWNTs via chemical vapor deposition (CVD) are known to those of ordinary skill in the art, and generally require a catalytically active surface, which may be the substrate itself or a catalyst applied to the substrate, a carbon feedstock, and heat. Suitable materials for applying as a catalyst or for forming a catalytically active substrate for promoting the growth of MWNTs or SWNTs include but are not limited to nickel, cobalt, and iron. Suitable carbon feedstocks for growing MWNTs or SWNTs include but are not limited to acetylene, ethylene, benzene, carbon monoxide, and carbon dioxide. The nanotubes described in this disclosure need not be limited to carbon nanotubes. In particular, it is well-known that carbon nanotubes may be converted into boron carbide nanotubes by a post-processing step, and such tubes are electrically insulating.

Other examples are also presented in the present disclosure, and the various features described may form a basis for designing or modifying other processes and structures for carrying out equivalent purposes and/or achieving the equivalent advantages of the examples introduced herein.

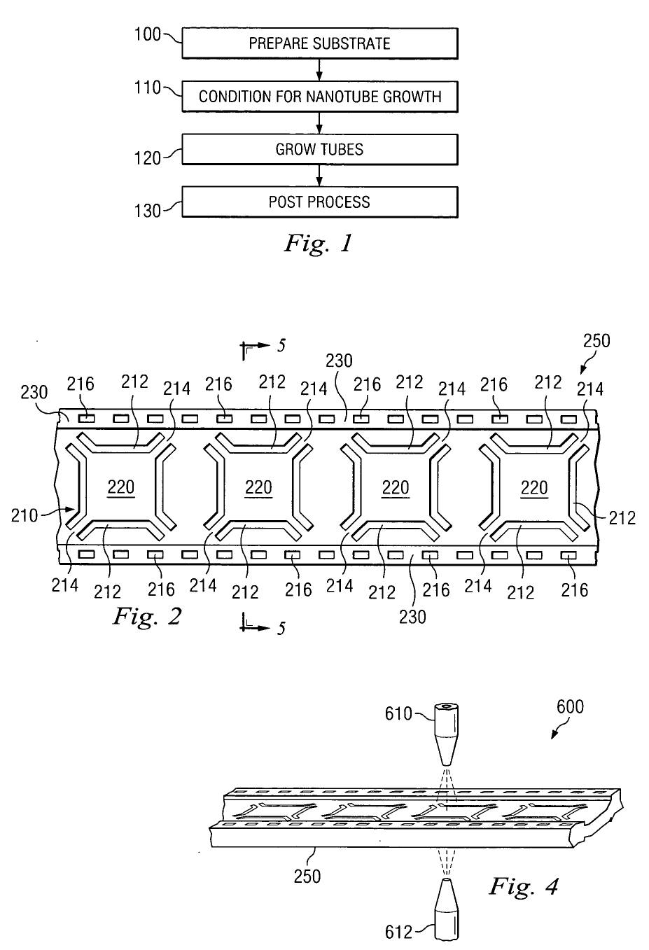

Referring now to FIG. 1, an exemplary method for preparing a thermal interface comprising arrays of aligned nanotubes according to the present disclosure is illustrated. In operation 100, a substrate is prepared, which preparation includes creating desired surface features on the substrate. An example of a substrate prepared in an exemplary operation 100 is illustrated in FIG. 2.

Referring now to FIG. 2, substrate 210 has been prepared to define a plurality of nanotube growth areas 220, which are referred to as “coupons”, on the substrate. A substrate having one or more coupons 220 formed along its length is also referred to herein as a “ribbon” 250. In one example, operation 100 provides a process in which a substrate is cut or etched to remove portions thereof so as to define at least coupon areas 220. According to one example, metal substrates are die-cut or laser-cut. According to another example, metal substrates are chemically or electrochemically etched. According to another example, ceramic or glass substrates are etched, molded, or cut via laser or water jet. According to another example, the substrate is electroplated up in a mold which defines the features. The processes of cutting, etching, plating, and molding are known to persons of ordinary skill in the art. Any of the methods described above is suitable to define a plurality of coupons 220 as surface features on the substrate.

Other surface features of substrate 210 that can be formed during the substrate preparation of operation 100 include grooves 212, tabs 214, slots 216 and raised edges 230. Grooves 212 illustrate portions of substrate 210 that were removed during operation 100, such as by the cutting and etching methods described above. Tabs 214 are that part of the substrate between grooves 212 that is not removed. Coupons 220 remain connected with the substrate 210 during manufacture of a thermal interface by way of tabs 214. When completed, the thermal interface may be released from the substrate 210 by severing tabs 214. Tabs 214 are illustrated in FIG. 2 at four corners of coupon 220. In other examples, however, tabs 214 may be formed anywhere along the perimeter of the coupon 220, and the coupon itself can be a shape other than the square shape illustrated in FIG. 2. Optional slots 216, which are also formed such as by cutting or etching, are sprocket holes that allow the substrate to be handled and advanced precisely, which can be of benefit when the thermal interfaces are prepared as a continuous process. The preparation process performed in operation 100 creates a substrate having opposing surfaces that are substantially identical in configuration. Thus, in the example illustrated in FIG. 2, the coupons 220, grooves 212, tabs 214 and slots 216 formed on a first surface of the substrate 210 translate to an opposing surface of the substrate 210.

Raised edges 230 may also be formed during operation 100, and, as will be described with respect to FIG. 5, provide a surface feature with which contact between respective coupons 220 can be prevented. Raised edges 230 can be formed by die stamping, folding, or electroplating. According to another example, raised edges 230 could be formed from a strip of material added to the edges of the substrate 210.

Referring again to FIG. 1, the opposing sides of the substrate are conditioned for nanotube growth in operation 110. In some examples, nanotube growth conditioning 110 includes locally activating an inactive catalytic substrate in those areas where nanotube growth is desired, such as coupons 220.

In other examples, nanotube growth conditioning 110 includes applying an inactive catalyst to substantially the entire area of the substrate, and then locally activating the catalyst in those areas where nanotube growth is desired, such as coupons 220.

In still other examples, nanotube growth conditioning 110 includes applying a mask to substantially the entire area of a catalytically active substrate, except for those areas where nanotube growth is desired.

In still other examples, nanotube growth conditioning 110 includes applying an active or inactive catalyst to substantially the entire area of a catalytically inactive substrate, and masking substantially all but those areas of the substrate where nanotube growth is desired. If an inactive catalyst is used in such an example, the catalyst can be activated either before or after masking.

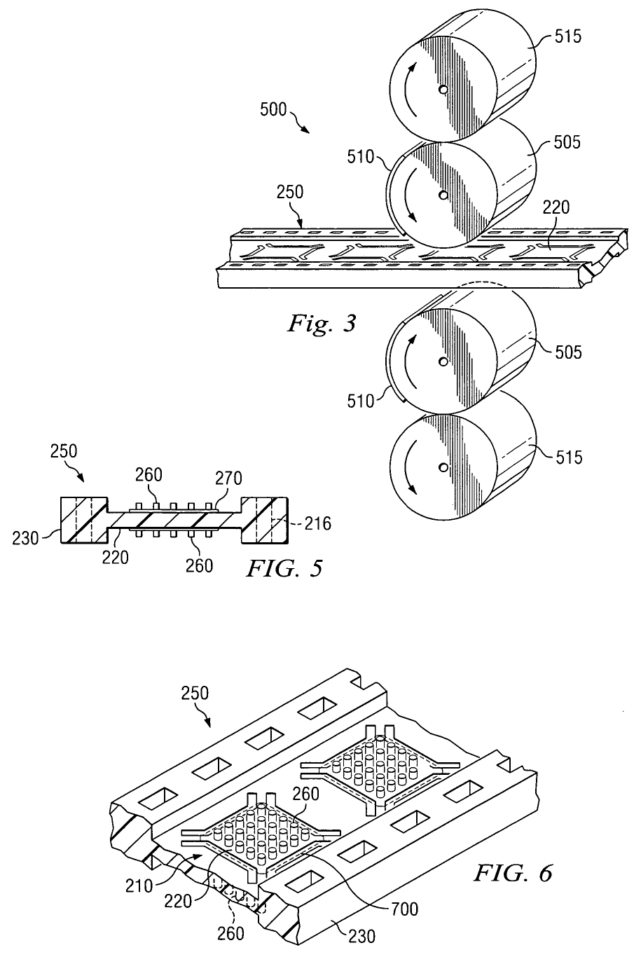

In still other examples, nanotube growth conditioning 110 includes applying an active or inactive catalyst to substantially only those areas of a catalytically inactive substrate where nanotube growth is desired. Such selective application can be accomplished by a device such as printing system 500 illustrated in FIG. 3. If an inactive catalyst is used in such an example, the catalyst can be activated locally, where it is deposited.

In yet other examples, nanotube growth conditioning 110 includes activating substantially the entire area of an inactive catalytic substrate, and then masking substantially all but those areas of the substrate where nanotube growth is desired.

In still other examples, the substrate has a nanotube growth catalyst deposited on substantially all areas of its opposing surfaces during its manufacture. In such an example, the catalyst is referred to as “pre-deposited” growth catalyst because the catalyst is deposited prior to operation 110. The pre-deposited growth catalyst is masked, for example by deposition of a passivating material during manufacture of the substrate, so that the catalyst is not exposed until nanotube growth is initiated in operation 120. Nanotube growth conditioning 110 includes exposing the pre-deposited growth catalyst on the coupon areas by removing the mask, which can be done according to methods known to those of ordinary skill in the art.

According to still other examples, nanotube growth conditioning 110 includes applying an activated catalyst on at least the coupons 220, and in some examples, on substantially the entire area of opposing surfaces of the ribbon 250. In a subsequent nanotube growth operation 120, nanotubes are selectively grown only on desired areas, such as on coupons 220, even though more of the substrate has exposed active catalyst. For example, a local heating source such as radiant heating or laser heating can be focused on the coupons 220, which will become the only areas on the substrate hot enough to grow nanotubes. In such an example, the thermal isolation provided by tabs 214 is sufficient to confine the heating area to the area of the coupons 220. Moreover, patterned deposition or activation of the catalyst is not necessary in such an example.

Activation of an inactive catalytic substrate or an inactive applied catalyst generally includes driving off non-metal parts of a compound, for example, by heating in a chemically reducing environment. In those examples where local activation is performed, the local activation may be accomplished by locally heating just the area to be activated, by, for example, radiant heating, laser heating, or other localized heating techniques well-known to those of ordinary skill in the art. Non-activated areas of inactive catalyst will not grow nanotubes, so local activation can supplant explicit masking.

In those examples where an active or inactive catalyst is applied to a masked substrate, the catalyst can be applied, for example, by spraying or dipping to cover substantially all but the masked areas with catalyst. According to another example, the mask may not be physically applied to the substrate, but may be a shadow mask, also known as a stencil mask, through which the catalyst is applied to the substrate. Shadow masks are well known to those of ordinary skill in the art, and function by physically blocking passage of material the way a stencil blocks spray paint.

Masking as referred to in each of the foregoing examples is a technique known to those of ordinary skill in the art, and is designed to prevent deposition of materials on or exposure of parts of a substrate that are masked. Numerous masking techniques are known to those of ordinary skill in the art, and any such method is suitable for application of a mask to the substrate. For example, masking techniques based around photolithography are suitable. One example of a suitable mask for use with the present examples is a resist mask. If the mask is used to control catalyst deposition and subsequently removed, it need not be robust. However, if the mask is used to cover a catalytically active substrate during CVD growth of nanotubes, the mask must be made of a material that is robust enough to survive the nanotube growth conditions.

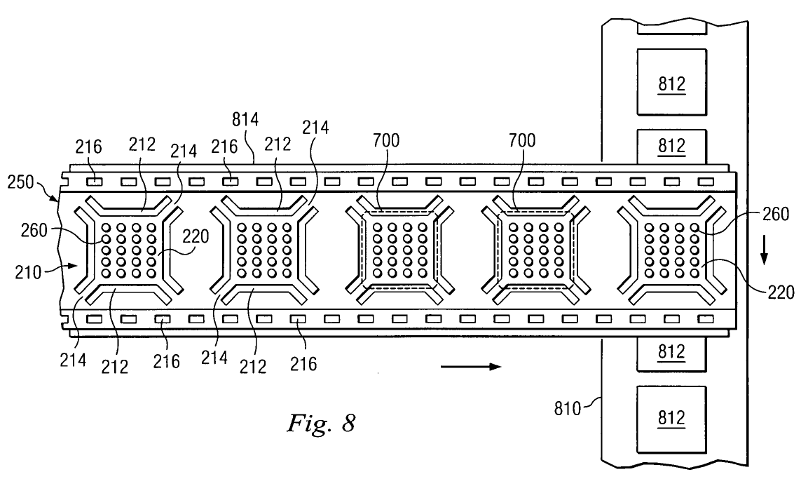

If a mask is applied to the substrate, the mask can be removed at any point prior to growth of the nanotubes, or can be left on the substrate during and after growth of the nanotubes. As will be described further with respect to FIG. 8, removal of the mask, if one was applied, is not necessary for the use and operation of a thermal interface device 700 because even if a mask were applied, the coupon area 220 is not masked. In addition, as will also be described further with respect to FIG. 8, the portion of the ribbon 250 that is applied to a component, such as a heat-generating device or a heat sink, is the thermal interface device 700. The thermal interface device comprises a coupon area 220 with nanotubes 260 grown thereon. The coupon area is not masked and the nanotubes are exposed, regardless of whether a mask was applied to the remainder of the substrate.

Referring now to FIG. 3, one example of a nanotube conditioning system operable to apply a mask or catalyst to opposing surfaces of a ribbon or coupon is printing system 500. Printing system 500 comprises upper and lower print wheels 505, each having a print stamp 510 thereon and a corresponding upper and lower material wheel 515. The upper and lower print wheels 505 rotate counter clockwise with respect to each other, but at the same speed.

The print stamp 510 on each print wheel has an area that corresponds to the pattern of mask or catalyst, whether active or inactive, to be applied to the ribbon 250 or coupon 220. If the printing system 500 is being used to apply a mask, then the print stamp 510 has a pattern to cover substantially all areas of the substrate with a mask, except for those where nanotube growth is desired, such as coupon areas 220. If the printing system 500 is being used to apply catalyst, then the print stamp 510 has a pattern to cover those areas of the substrate where nanotube growth is desired, such as coupon areas 220. When the print stamp 510 is used to apply catalyst, catalyst can be applied to substantially just those areas of the substrate where nanotube growth is desired, regardless of whether the substrate is masked or unmasked.

The upper and lower material wheels 515 are operable to provide material (i.e., active or inactive catalyst, or mask) to the print stamp 510 of the corresponding upper and lower print wheel 505. The upper and lower material wheels 515 are positioned so as to contact the print stamp 510 of the corresponding upper and lower print wheel 505 as the print wheel rotates. The upper and lower material wheels may be stationary dispensers of material for print wheels 505, or they may rotate.

The ribbon 250 is fed, such as by a motor-driven conveyor or pulling by an end reel, so as to pass between the upper and lower print wheels 505. Thus, the ribbon comes into contact with the print stamp 510 of each wheel. The print wheels 505 may be indexed with slots 216 so that coupon areas 220 will be aligned with the print stamps 510 as the print wheels rotate. In another method, the alignment may be performed optically, by recognizing features on the ribbon 250 and aligning with the print stamp 510. In addition to such indexing, the upper and lower print wheels 505 rotate at the same speed, thus, their respective print stamps 510 simultaneously contact both surfaces of the ribbon 250 at the same point along the length of the ribbon 250. In this manner, a substantially identical mask pattern is applied to opposing surfaces of the ribbon 250.

Another example of a nanotube conditioning system operable to apply a catalyst to opposing surfaces of a substrate is a spray system, such as spray system 600 illustrated in FIG. 4. Ribbon 250 is fed into spray system 600, such as by a motor-driven conveyor or pulling by an end reel. Catalyst, in the form of a liquid solution containing metallic catalyst in a salt form or in the form of metallic nanoparticles suspended in a fluid, is sprayed on opposing surfaces of the substrate by spray nozzle 610 as the substrate travels through the spray system. The nozzle on the bottom sprays with sufficient velocity such that the liquid overcomes gravity to coat the substrate. Preparation of catalyst in the form of a liquid solution containing metallic catalyst in a salt form is known to those of ordinary skill in the art.

In some examples where spray system 600 is employed, those areas of the substrate where growth of nanotubes is not desired are masked prior to entry of the substrate into the spray system 600. For example, masking is performed to define coupon areas 220 on the substrate according to any masking technique known in the art or described herein, such as a shadow or stencil mask. Because of the mask, only coupon areas 220 are exposed to spray-coating with the catalyst, and areas covered by the mask either repel the catalyst, or are coated and subsequently removed when the mask is removed after catalyst deposition and before CVD growth. In other examples, when spray system 600 is employed, an inactive catalyst is applied to substantially all areas of the substrate, and the applied inactive catalyst is activated in a subsequent step only in those areas where nanotube growth is desired.

In addition to the roller-based printing described above, other printing techniques known to those of ordinary skill in the art, such as block printing, are suitable for use with nanotube growth conditioning as described herein. In addition to spraying and printing as described above, other methods for applying a catalyst to a substrate are suitable for use with the present examples. Such methods include but are not limited to electrochemical deposition, physical vapor deposition and floating catalyst deposition. Alternatively, the catalyst may be applied as a dry powder of either the metal salt form, or of metal nanoparticles. Alternatively, the catalyst may be deposited as metal nanoclusters using a variety of methods well-known to those in the field, such as sputtering or thermal evaporation. By employing such methods, catalyst can be applied to opposing surfaces of a substrate as described herein.

Metallic nanoparticles are generally active as deposited, while metallic salts generally require activation, such as by chemical reduction. Inactive catalysts are activated to promote the growth of nanotubes by driving off the non-metal parts of the compound, by for example, heating the catalyst in a chemically reducing environment, such as by heating in hydrogen gas.

The size of the area of the substrate to be conditioned for nanotube growth depends at least in part on the size of the desired area for growing nanotubes. The desired area for growing nanotubes depends at least in part on the desired size of the thermal interface device. For example, in certain applications, it may be desired to have a thermal interface device approximately the same size as the component to which it will be applied, while in other applications, it may be desired to have a thermal interface device smaller in size than the component to which it will be applied, thus leaving an outer perimeter, such as between the component and the thermal interface device, where nanotubes were not grown. Those of ordinary skill in the art can determine, without undue experimentation, the desired size for a thermal interface device, and in turn the size of the area to be defined for nanotube growth.

Subsequent to nanotube conditioning, nanotubes are grown on the coupons in operation 120 via catalytic chemical vapor deposition (CVD), thereby forming substantially complete thermal interfaces. Methods for catalytic growth of carbon MWNTs and carbon SWNTs via CVD are known to those of ordinary skill in the art, and such persons can, without undue experimentation, determine suitable deposition temperatures and rates, as well as the thickness of the catalyst layer. Generally, however, growth of carbon nanotubes via CVD requires a catalytically active surface, (which may be the substrate itself or a catalyst applied to the substrate as described above), a carbon feedstock, and heat.

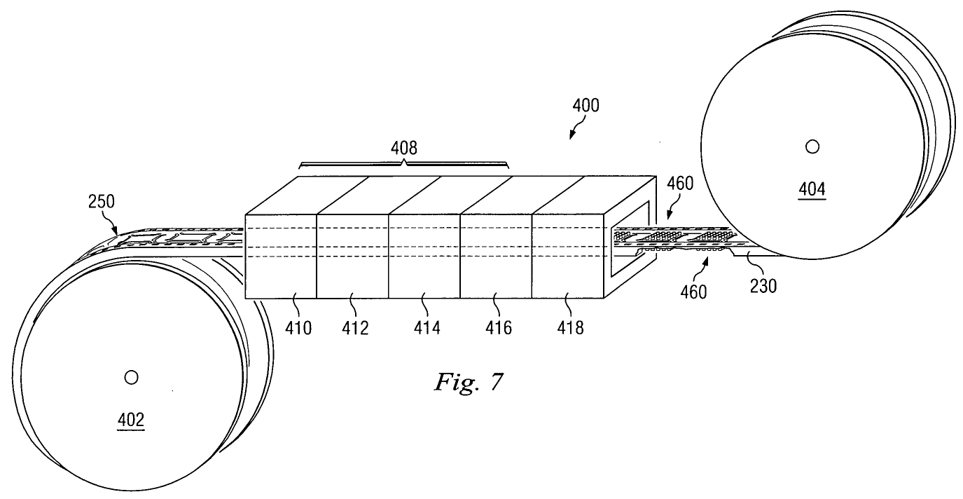

Referring to FIG. 5, it is illustrated that nanotubes 260 are grown to a height that is less than the height of the edges 230 of the substrate 210. The presence of the raised edges 230 enables further handling of the substrate 210, such as is described with respect to FIG. 7, without compromising the integrity of the nanotubes 260 on the coupon areas 220. For example, if the ribbon is wound onto a reel or multiple ribbons are stacked after growth of the nanotubes, the raised edges provide a height buffer that prevents the nanotubes from being damaged by contact.

Referring to FIG. 6, another example of nanotubes grown to a height that is less than the height of the edges 230 of the substrate 210 is illustrated. As with the other figures herein, FIG. 6 is not drawn to scale, and certain illustrations therein may be exaggerated for the purposes of clarity. A thermal interface device 700 according to the present examples comprises a coupon area 220 with nanotubes 260 grown on opposing surfaces thereof. As illustrated in FIG. 6, the raised edges 230 of the ribbon 250 are thicker than the height of the nanotubes 260 on the coupon 220, and provide a height buffer that prevents the nanotubes from being damaged by contact.

According to certain examples, the density of the growth of nanotubes on the substrate provides the nanotubes with sufficient support to remain substantially perpendicularly aligned with respect to the substrate. In such an example, the ribbon of thermal interface devices can proceed to packaging for shipping to an end user, or directly to application to a heat-generating device. According to other examples, however, a support material 270 (FIG. 5) is applied around the nanotubes 260 on one or both opposing surfaces of the substrate during a post-processing operation 130. The support 270 helps to keep the nanotubes substantially perpendicularly aligned and prevent the nanotubes from being crushed, undergoing sideways adhesion to each other, or peeling off the substrate. If employed, the support is preferably an elastomer, such as polyisoprene, polybutadiene, polyisobutylene, or polyurethane. Those of ordinary skill in the art can, through the exercise of routine experimentation, select an elastomer suitable for use with the present examples. Exemplary methods for applying a support that are suitable for use with the present examples include spray coating or dipping of one or both sides of the substrate. For example, to apply the support to opposing surfaces of the substrate by spray coating, a spray system, such as spray system 600 described above, can be employed. If applied, the support should not be applied to a height greater than that of the nanotubes, but rather the support should be applied so as to leave exposed the ends of the nanotubes that are distal from the substrate.

In other examples of optional post-processing 130, electrically conducting nanotubes, such as carbon nanotubes, are converted into an electrically insulating material, such as boron carbide nanotubes. Techniques for converting carbon nanotubes into boron carbide nanotubes are known to those of ordinary skill in the art.

The method of preparing a thermal interface illustrated by FIG. 1 may be performed as a series of individual steps, or combined into a continuous process as described further herein with respect to FIG. 7.

Referring now to FIG. 7, a system 400 for preparing a thermal interface device is illustrated. Thermal interface preparation system 400 includes a nanotube conditioning subsystem 408 and a nanotube growth system 416. In the example illustrated in FIG. 7, nanotube conditioning system 408 includes a masking system 410, a catalyst application system 412 and a catalyst activation system 414. The exemplary system illustrated in FIG. 7 also includes a post-processing system 418. The substrate is fed through each of these systems to result in a ribbon of thermal interface devices.

In the exemplary system 400 illustrated in FIG. 7, nanotube conditioning includes masking, which occurs in masking system 410, application of an inactive catalyst, which occurs in catalyst application system 412, and catalyst activation, which occurs in catalyst activation system 414. However, as described above with respect to operation 110, a mask may or may not be used, the catalyst may be applied or may be a catalytic substrate, and the catalyst or catalytic substrate may or may not require either general or local activation. Thus, in other examples of system 400, nanotube conditioning subsystem 408 may not include each of masking system 410, catalyst application system 412 and catalyst activation system 414. Systems such as printing system 500 or spraying system 600 can be implemented in masking system 410 and catalyst application system 412 to apply mask or catalyst to the substrate. Activation system 414 implements conditions for activating an inactive catalyst applied to the substrate or activating an inactive catalytic substrate, such as by heating in a chemically reducing environment. The heating can done for example, by radiant heating or laser heating.

Nanotube growth system 416 is preferably a CVD chamber operating under conditions that will grow nanotubes on opposing surfaces of the substrate. Optional post-processing system 418 in the present example includes a spray system, such as spray system 600, for applying a support material around the nanotubes. Sprayers, blowers, dryers, and other devices can also be placed in any of the subsystems for further treatment of the substrate fed therethrough. Nanotubes 460 are grown on opposing areas on the substrate, preferably to a height that is less than the thickness of the raised edges 230.

As illustrated in FIG. 7, a ribbon 250 is conveyed through thermal interface preparation system 400 from a feed reel 402, although in other examples, the ribbon 250 is fed directly from a substrate preparation system that implements a preparation process as described with respect to operation 100. Methods for feeding the ribbon 250 to and through the system 400 are known, and include conveying the ribbon 250 on a motor-driven conveyor or pulling it through the system 400 via a take-up reel 404.

Thus, according to one example, as the ribbon exits the system 400, the ribbon is wound onto a take-up reel, roll, wheel, or sprocket, referenced as take-up reel 404 in FIG. 7. According to such an example, slots 216 are formed into the substrate as described above with respect to operation 100, and the ribbon 250 is initially engaged with the take-up reel 404 by teeth on the take-up reel 404. The teeth on the take-up reel 404 initially engage the slots 216 of an incoming feed of the ribbon 250. The take-up reel 404 is caused to rotate by conventional methods, such as motor-driven. As described above with respect to operation 130, the nanotubes 260 are preferably grown to a height that is less than the thickness of the raised edges 230 of the substrate. Thus, if the substrate is wound onto a reel such as take-up reel 404, the raised edges 230 provide a height buffer that prevents the nanotubes from being damaged by contact. Substrate wound onto take-up reel 404 can be further processed into a plurality of ribbons for shipping and supplying end users. The end user applies a thermal interface device 700 from the ribbon to a component whereby the thermal interface device 700 conducts heat to or from the component. For example, a thermal interface device 700 can be applied to a heat generating device or a heat sinking device.

According to another example, the ribbon 250 is not wound onto a take-up reel, but rather is fed directly from the system 400 into a packaging device that cuts and packages the ribbon 250, or a system that applies the thermal interface devices 700 to heat generating devices and/or heat sinks.

Referring now to FIG. 8, one example of a system for applying a thermal interface device to a heat generating or heat sinking device is illustrated. FIG. 8 illustrates a ribbon 250 comprising a plurality of thermal interface devices 700 engaged with a substrate conveyor 814 lying in a plane above a plurality of components 812 that are disposed on a component conveyor 810. Components 812 can be heat generating devices or heat sinks.

According to one example, the ribbon 250 is engaged with the substrate conveyor 814 by way of slots 216. The substrate conveyor 814 is operated to run perpendicular to the direction in which the component conveyor 810 is operated to run. By way of this configuration, respective ones of thermal interface devices 700 are aligned with respective ones of components 812. An individual thermal interface device 700 is applied to a component 812 as it passes over the component 812 by removing the tab portions 214, thereby freeing the coupon areas 220 from the substrate 210. Removal of tab portions 214 can be accomplished by a variety of devices and methods. According to one method, the tab portions 214 are punched out by a die, thereby freeing thermal interface device 700 from the substrate 210. Once freed, the thermal interface device 700 remains in place on its respective component 812 until further processed due to surface adhesion forces. In further processing where the component 812 is a heat-generating device, the thermal interface device 700 is capped with a heat sink. In an example where the component 812 is a heat sink, the thermal interface device 700 is capped with a heat-generating device. In either example, thermal interface device 700 provides thermal conductivity between the heat-generating device and the heat sink.

According to one example, the ribbon 250 is provided for engagement with the substrate conveyor 814 from a take-up reel 404 at the end of a process line illustrated by system 400. According to another example, ribbon 250 is not wound onto a take-up reel. Rather, as the ribbon 250 exits system 400, it is fed to a system for applying a thermal interface device to a component as described above with respect to FIG. 8. According to yet another example, an end user receives only a portion of the ribbon from the take-up reel 404, and therefore supplies his own device for providing that portion of the ribbon for engagement with the substrate conveyor 814. It is within the means of those of ordinary skill in the art to determine and operate a suitable device for providing the substrate to a system for application to a component such as a heat-generating device or a heat sink. As a device such as substrate conveyor 814 is employed after the substrate exits the system 400, and regardless of whether the substrate conveyor 814 is fed from a take-up reel 404, the substrate conveyor is referred to as being disposed subsequent to system 400.

Applications for a thermal interface device prepared according to the present examples include, but are not limited to, use as a heat transfer device between a semiconductor die and a heat sink or between a microprocessor and a heat sink. According to one example, the thermal interface device may be a metallic component suitable to act as a lid in packaging an integrated circuit. According to this example, the nanotubes on the inside of the lid contact heat-generating components inside the package, and the nanotubes on the outside of the lid contact the heat-sinking component directly. Other applications include using the thermal interface device to conduct heat away from integrated circuits. Essentially, a thermal interface device prepared according to the present examples has a wide variety of applications where thermal conductivity is desired.

The present examples have been described relative to exemplary compositions and methods. Improvements or modifications that become apparent to persons of ordinary skill in the art after reading this disclosure are deemed within the spirit and scope of the application. It is understood that several modifications, changes and substitutions are intended in the foregoing disclosure. Accordingly, it is appropriate that the appended claims be construed broadly and in a manner consistent with the scope of the present disclosure.

1. A method of preparing a plurality of thermal interface devices comprising:
conditioning a plurality of coupons on opposing surfaces of a substrate for nanotube growth; and
growing thermally conducting nanotubes on opposing surfaces of the coupon, which nanotubes are substantially perpendicularly aligned with respect to the substrate; and
wherein the coupons with the nanotubes grown on opposing surfaces thereof comprise the plurality of thermal interface devices.

2. The method of claim 1 further comprising:
forming the plurality of coupons by at least one of die-cutting, laser-cutting, water-jet cutting, chemical etching, electro-chemical etching, machining, molding, electroplating, electroless plating, and casting of the substrate.

3. The method of claim 2 further comprising:
forming at least one of grooves, tabs, slots and raised edges on the substrate.

4. The method of claim 1 further comprising defining a plurality of tabs on the substrate, wherein the coupons are connected to the substrate by the tabs.

5. The method of claim 1 wherein the substrate comprises an inactive catalytic substrate, and the conditioning for nanotube growth comprises locally activating the inactive catalytic substrate in the coupons by heating the coupons in a reducing environment to effect chemical reduction of the inactive catalyst into a catalytically active form.

6. The method of claim 1 wherein the conditioning for nanotube growth comprises:
applying an inactive catalyst to at least the coupons on the opposing surfaces of the substrate; and
activating the inactive catalyst.

7. The method of claim 1 wherein the substrate comprises a catalytically active substrate, and the conditioning for nanotube growth comprises:
applying a mask to substantially all areas of the opposing surfaces of the catalytically active substrate, except for the coupons.

8. The method of claim 1, wherein the substrate comprises a catalytically inactive substrate, and the conditioning for nanotube growth comprises:
applying an active catalyst to substantially all areas of the opposing surfaces of the substrate; and
masking substantially all areas of the substrate, except for the coupons.

9. The method of claim 1, wherein the substrate comprises a catalytically inactive substrate, and the conditioning for nanotube growth comprises:
applying an inactive catalyst to substantially all areas of the opposing surfaces of the substrate;
masking substantially all areas of the substrate, except for the coupons; and
activating the inactive catalyst left unmasked on the coupons.

10. The method of claim 1, wherein the conditioning for nanotube growth comprises:
applying an active catalyst to substantially only the coupons on opposing surfaces of the substrate.

11. The method of claim 1, wherein the conditioning for nanotube growth comprises:
applying an inactive catalyst to substantially only the coupons on opposing surfaces of the substrate; and
locally activating the inactive catalyst.

12. The method of claim 1, wherein the substrate comprises an inactive catalytic substrate, and the nanotube growth conditioning comprises:
activating substantially all areas of the opposing surfaces of the inactive catalytic substrate; and
masking substantially all areas of the opposing surfaces of the substrate, except for the coupons.

13. The method of claim 1, wherein the conditioning for nanotube growth comprises:
exposing catalyst deposited on the substrate during manufacture of the substrate which catalyst was covered by a passivating material prior to exposure.

14. The method of claim 1 wherein:
the conditioning for nanotube growth comprises applying an activated catalyst on at least the coupons; and
the growing of nanotubes comprises locally applying growing conditions to only the coupons such that the nanotubes grow only on the coupons.

15. The method of claim 14 wherein the local application of growing conditions comprises applying heat to substantially only the coupons.

16. The method of claim 1 further comprising:
controlling perpendicular height of the nanotubes relative to the substrate, such that a first substrate can be stacked on a second substrate without the nanotubes on the first substrate touching the nanotubes on the second substrate.

17. The method of claim 1 further comprising, prior to growing the nanotubes, applying a mask to the opposing surfaces of the substrate except for the coupon areas.

18. The method of claim 17 wherein the masking comprises
feeding the substrate between an upper print stamp containing masking material and a corresponding lower print stamp containing masking material; and
causing opposing surfaces of the substrate to come into contact with the upper print stamp and lower print stamp respectively, thereby causing the masking material to be deposited on the contacted areas of the substrate.

19. The method of claim 17 wherein the masking comprises depositing the masking material through at least one of a shadow mask and a stencil mask.

20. The method of claim 1 wherein the conditioning for nanotube growth comprises:
feeding the substrate between an upper print stamp containing catalyst and a corresponding lower print stamp containing catalyst; and
causing opposing surfaces of the substrate to come into contact with the upper print stamp and lower print stamp respectively, thereby causing the catalyst to be deposited on the contacted areas of the substrate.

21. The method of claim 1 wherein the conditioning for nanotube growth comprises:
feeding the substrate through a spraying system with sprayers operable to spray one of catalyst and masking material on each of the opposing surfaces of the substrate; and
spraying both sides of the substrate as the substrate is fed through the spraying system.

22. The method of claim 21 wherein the spraying is done through at least one of a shadow mask and a stencil mask, such that the catalyst or masking material is applied to substantially just the coupons on the substrate.

23. The method of claim 1 wherein the growing of the nanotubes comprises a catalyzed chemical vapor deposition process.

24. The method of claim 23 wherein the catalyst is selected from the group consisting of nickel, cobalt, and iron.

25. The method of claim 1 further comprising post-processing the substrate after the growing of nanotubes on the coupons to further process the coupons for use as thermal interface devices.

26. The method of claim 25 wherein the post-processing comprises:
applying an elastomeric support around the nanotubes grown on at least one of the opposing surfaces of the substrate.

27. The method of claim 1 wherein the substrate comprises a material selected from the group consisting of metals, glass and ceramics.

28. The method of claim 27 wherein the substrate comprises a metal selected from the group consisting of steel, stainless steel, copper, and nickel.

29. The method of claim 1 wherein the growing of the nanotubes comprises growing multi-walled carbon nanotubes.

30. The method of claim 1 wherein the growing of the nanotubes comprises growing single-walled carbon nanotubes.

31. The method of claim 1 wherein grown carbon nanotubes are subsequently post-processed into another form of nanotube.

32. The method of claim 1 wherein different types of nanotubes are grown on each of the opposing surfaces of the substrate.

33. The method of claim 1 wherein the growing of the nanotubes comprises growing thermally conductive carbon nanotubes, and further comprising:
post-processing the substrate to convert the carbon nanotubes into a thermally conducting and electrically insulating material.

34. A system comprising:
a nanotube conditioning system operable to receive a feed of a substrate and to condition areas for nanotube growth on opposing surfaces of the substrate; and
a nanotube growth system operable to receive a feed of the substrate from the nanotube conditioning system and to grow nanotubes on the conditioned areas.

35. The system of claim 34 further comprising
a post-processing system operable to receive a feed of the substrate from the nanotube growth system and to further process the conditioned areas with nanotubes grown thereon for use as thermal interface devices.

36. The system of claim 34 wherein the nanotube conditioning system comprises at least one of a masking system, a catalyst application system and a catalyst activation system.

37. The system of claim 36 wherein the nanotube conditioning system comprises a masking system, which masking system comprises one of a print system and a spray system.

38. The system of claim 37 wherein the masking system comprises a print system, which print system comprises an upper print stamp containing masking material and a corresponding lower print stamp containing masking material, which upper print stamp and lower print stamp come into contact with opposing surfaces of the substrate thereby causing the masking material to be deposited on the contacted areas of the substrate.

39. The system of claim 37 wherein the masking system comprises a spray system, which spray system comprises sprayers operable to spray a masking material on opposing surfaces of the substrate as the substrate is fed through the spray system.

40. The system of claim 36 wherein the nanotube conditioning system comprises a catalyst application system, which catalyst application system comprises one of a print system and a spray system.

41. The system of claim 40 wherein the catalyst application system comprises a print system, which print system comprises an upper print stamp containing catalyst and a corresponding lower print stamp containing catalyst, which upper print stamp and lower print stamp come into contact with opposing surfaces of the substrate thereby causing the catalyst to be deposited on the contacted areas of the substrate.

42. The system of claim 40 wherein the catalyst application system comprises a spray system, which spray system comprises sprayers operable to spray a catalyst on opposing surfaces of the substrate as the substrate is fed through the spray system.

43. The system of claim 36 wherein the catalyst activation system comprises a heat source operable to cause at least one of activation of a catalyst applied on the substrate and activation of an inactive catalytic substrate.

44. The system of claim 34 further comprising:
a substrate preparation system preceding the nanotube conditioning system, which substrate preparation system forms the areas for nanotube growth by at least one of die-cutting, laser-cutting, water-jet cutting, chemical etching, electro-chemical etching, machining, molding, electroplating, electroless plating, and casting.

45. The system of claim 34 further comprising:
a post-processing system operable to receive a feed of the substrate from the nanotube growth system and to apply an elastomer around the nanotubes grown on at least one surface of the substrate.

46. The system of claim 34 further comprising
a substrate conveyor disposed subsequent to the nanotube growth system;
a component conveyor disposed in a plane above or below the substrate conveyor, wherein the substrate conveyor conveys substrate in a direction perpendicular to the direction in which the component conveyor conveys components; and
a device for freeing the areas of the substrate with nanotubes grown thereon from the substrate as the substrate is conveyed by the substrate conveyor and applying a freed area of the substrate to a corresponding one of a component conveyed on the component conveyor.

47. A thermal interface device comprising:
a first array of nanotubes grown by catalyzed chemical vapor deposition on a surface of a substrate; and
a second array of nanotubes grown by catalyzed chemical vapor deposition on an opposing surface of the substrate,
wherein heat can be transported from a heat-generating device in contact with the first array of nanotubes, through the substrate, and into the second array of nanotubes.

48. The thermal interface device of claim 47 wherein the nanotubes in the first and second arrays are substantially perpendicularly aligned with respect to the substrate.

49. The thermal interface device of claim 47 further comprising:
a support disposed about the nanotubes on at least one of the opposing surfaces of the substrate.

50. The thermal interface device of claim 47 wherein the substrate comprises a material selected from the group consisting of metals, non-metals, glass and ceramics.

51. The thermal interface device of claim 50 wherein the substrate comprises a metal selected from the group consisting of steel, stainless steel, copper, nickel.

52. The thermal interface device of claim 47 wherein the substrate comprises an electrically insulating material.

53. The thermal interface device of claim 47 wherein at least one of the arrays of nanotubes comprise multi-walled carbon nanotubes.

54. The thermal interface device of claim 47 wherein at least one of the arrays of nanotubes comprises single-walled carbon nanotubes.

55. The thermal interface device of claim 47 wherein at least one of the arrays of nanotubes comprises thermally conducting and electrically insulating nanotubes.

56. The thermal interface device of claim 47 wherein the nanotubes comprising the first array are a different type than the nanotubes comprising the second array.

57. The thermal interface device of claim 47 wherein the nanotubes in each of the first and second arrays have a height that is less than the height of the surrounding substrate.
